(19) United States
(12) Patent Application Publication
(10) Pub. No.: US 2024/0120771 A1
(43) Pub. Date: Apr. 11, 2024

(54) Monitoring and optimisation of electricity consumption

(71) Applicant: SAGEMCOM ENERGY & TELECOM SAS, RUEIL MALMAISON (FR)

(72) Inventors: Henri TEBOULLE, RUEIL MALMAISON (FR); Christophe GRINCOURT, RUEIL MALMAISON (FR)

(21) Appl. No.: 18/469,869

(22) Filed: Sep. 19, 2023

(30) Foreign Application Priority Data
Sep. 29, 2022 (FR) FR2209908

(51) Int. Cl. H02J 13/00; G01R 21/133

(52) U.S. Cl. CPC H02J 13/00002; G01R 21/1331; H02J 13/00036

(57) ABSTRACT

A monitoring method uses an electricity meter arranged to measure an electricity consumption of an installation and including a current limiter arranged to selectively limit a current supplied to the installation. The monitoring method includes he steps, repeated each current day, for each current period of a predetermined set of at least one successive period defined in the current day, of: verifying a first predetermined condition associated with said current period; if the first predetermined condition is verified, activating the current limiter to limit the current supplied to the installation until the end of said current period.

### DESCRIPTION

The invention relates to the field of so-called “smart” electricity meters.

### BACKGROUND OF THE INVENTION

Currently, innovative and effective solutions are sought which make it possible to limit the electricity consumption of end users (subscribers) connected to the electricity network. It is clear that limiting electricity consumption of everyone not only has an undeniable ecological interest, but is also very advantageous for the buying power of users.

A solution is known for reducing electricity consumption, which uses electricity load shedders.

An electricity load shedder is a piece of equipment which is installed at the user's place, close to the meter. The electricity load shedder cuts off the power to certain non-priority appliances at the time of the current draw, when the consumption exceeds a certain threshold. The non-priority appliances in question, as well as the load shedding sequences, can be defined by the user. The non-priority appliances typically comprise electric radiators and the hot water tank.

This solution is effective and makes it possible, not only to make significant energy savings, but also to avoid breaking the circuit of the installation when the power sought is too high.

However, this solution requires a specific and personalised installation at the user's place, and is therefore relatively expensive and complex to implement.

### AIM OF THE INVENTION

The invention aims to control and to optimise the electricity consumption of a user, which is simple and inexpensive to implement.

### SUMMARY OF THE INVENTION

In view of achieving this aim, a monitoring method is proposed, using an electricity meter arranged to measure an electricity consumption of an installation and comprising a current limiter arranged to selectively limit a current supplied to the installation, the monitoring method comprising the steps, repeated each current day, for each current period of a predetermined set of at least one successive period defined on the current day, of:
verifying a first predetermined condition associated with said current period;
if the first predetermined condition is verified, activating the current limiter to limit the current supplied to the installation until the end of said current period.

The monitoring method, which can be implemented by the meter itself or remotely, therefore makes it possible, each current day, to limit the electricity consumption of the installation based on predetermined conditions associated with periods of the current day. The component(s) forming the current limiter is/are directly integrated in the meter and is/are the same for all meters, such that the implementation of the monitoring method does not require any particular intervention, nor specific and personalised installation at the user's place.

In addition, a monitoring method is proposed, such as described above, the electricity meter comprising, in addition, a cutoff member arranged to selectively cut off the current supplied to the installation, the monitoring method further comprising the steps, for each current period, of:
verifying a second predetermined condition associated with said current period;
if the second predetermined condition is verified, operating the cutoff member so as to cut off the current supplied to the installation until the end of said current period.

In addition, a monitoring method is proposed, such as described above, wherein the first predetermined condition is that a cumulated electricity consumption of the installation on said current period is greater than a first predetermined threshold.

In addition, a monitoring method is proposed, such as described above, wherein the second predetermined condition is that a cumulated electricity consumption of the installation on said current period is greater than a second predetermined threshold, itself greater than the first predetermined threshold.

In addition, a monitoring method is proposed, such as described above, wherein the first predetermined threshold and/or the second predetermined threshold depend on said current period and/or on said current day and/or on a period of the year to which said current day belongs.

In addition, a monitoring method is proposed, such as described above, wherein the verification of the first predetermined condition consists of verifying, in a predefined table, that said current period is associated with a first piece of information, according to which the current supplied to the installation must be limited for the whole of said current period.

In addition, a monitoring method is proposed, such as described above, wherein the verification of the second predetermined condition consists of verifying, in the predefined table, that said current period is associated with a second piece of information, according to which the current supplied to the installation must be cut off for the whole of said current period.

In addition, a monitoring method is proposed, such as described above, the meter in addition comprising a cutoff member arranged to selectively cut off the current supplied to the installation, the cutoff member comprising a switch for each phase of a distribution network to which the installation is connected, the current limiter comprising, for each switch of the cutoff member, a relay and a resistive component mounted in parallel of the switch, the activation of the current limiter to limit the current supplied to the installation comprising the steps of closing the relay(s) simultaneously, then, of opening the switch(es) simultaneously.

In addition, an electricity meter is proposed, arranged to measure an electricity consumption of an installation, the electricity meter comprising a current limit arranged to selectively limit a current supplied to the installation, the electricity meter further comprising a processing unit arranged to implement the monitoring method such as described above.

In addition, an electricity meter is proposed, such as described above, the electricity meter in addition comprising a cutoff member arranged to selectively cut off the current supplied to the installation, the cutoff member comprising a switch for each phase of a distribution network to which the installation is connected, the current limiter comprising, for each switch of the cutoff member, a relay and a resistive component mounted in parallel of the switch, the processing unit being arranged, to activate the current limiter, to close the relay(s) simultaneously, then to open the switch(es) simultaneously.

In addition, a computer program is proposed, comprising instructions which lead to the processing unit of the electricity meter such as described above, executing the steps of the monitoring method such as described above.

In addition, a recording medium which can be read by a computer is proposed, on which the computer program such as described above is recorded.

The invention will be best understood in the light of the description below of particular, non-limiting embodiments of the invention.

### BRIEF DESCRIPTION OF THE DRAWINGS

Reference will be made to the accompanying drawings, wherein:

FIG. 1 represents a single-phase electricity meter;

FIG. 2 represents steps of a monitoring method;

FIG. 3 represents a three-phase electricity meter.

### DETAILED DESCRIPTION OF THE INVENTION

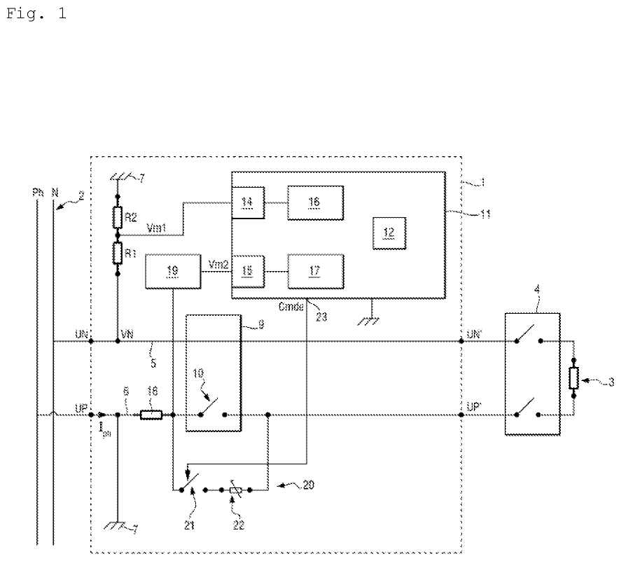

In reference to FIG. 1, the invention is first implemented in a single-phase electricity meter 1.

The meter 1 is intended to measure an electrical energy supplied by a source, in this case, by a distribution network 2, to the electrical installation 3 of a user (subscriber).

The distribution network 2 is a single-phase network and comprises a phase Ph and a neutral N. The meter 1 recovers the phase and the neutral of the network 2 to take metrological measurements.

A circuit breaker 4 is positioned at the boundary between the distribution network 2 and the installation 3. The circuit breaker 4, which can be actuated by the user, in particular has the role of protecting the installation 3 by opening when an over-current, resulting for example in a short-circuit downstream from the circuit breaker 4, occurs on the distribution network 2. In this case, “downstream” means on the side of the installation 3 and “upstream” means on the side of the distribution network 2.

The meter 1 comprises an input terminal UP connected to the phase Ph of the network 2 and an input terminal UN connected to the neutral N. The meter 1 in addition comprises two output terminals UP′ and UN′ connected to the circuit breaker 4, which is itself connected to the installation 3.

The meter 1 comprises a neutral conductor 5 connected to the input terminal UN.

The meter 1 in addition comprises a phase conductor 6 connected to the input terminal UP. The phase conductor 6 is connected to an electrical ground 7 of the meter 1.

The meter 1 in addition comprises a cutoff member 9 which comprises a switch 10 mounted on the phase conductor 6. The cutoff member 9 is, in particular, used to remotely cut off or re-establish the supply of the installation 3 (symbolised, in this case, by a charge) in case, for example, of terminating the subscription or not respecting the subscription contract.

The meter 1 also comprises an application part and a metrology part.

The application part (not represented) comprises an application microcontroller.

The metrology part comprises a metrological measurement microcontroller 11, the primary function of which is to produce measurements of a certain number of parameters making it possible to evaluate the electricity consumption of the installation 3.

The metrology part also comprises one or more memories 12 connected to or integrated in the microcontroller 11. At least one of these memories forms a recording medium which can be read by a computer, on which at least one computer program is recorded, comprising instructions which lead to the microcontroller 11 executing at least some of the steps of the monitoring method which will be described below.

The microcontroller 11 integrates a first analog-to-digital converter (ADC) 14, a second ADC 15, a voltage measuring module 16 and a current measuring module 17.

The metrology part also comprises a voltage sensor arranged to produce voltage measurements to evaluate a neutral voltage VN present on the neutral N.

In this case, a voltage sensor comprises a voltage divider bridge comprising a first measurement resistor R1 and a second measurement resistor R2. The first measurement resistor R1 has a first terminal connected to a neutral conductor 5 close to (and downstream from) the input terminal UN. The second measurement resistor R2 has a first terminal connected to the electrical ground 7. The second terminal of the first measurement resistor R1 and the second terminal of the second measurement resistor R2 are connected to one another and at an input of the microcontroller 11 to which is connected an input of the first ADC 14.

The voltage level measured Vm1 is adapted (thanks to the divider bridge R1, R2) in order to avoid saturations at the first ADC 14, and so as to apply at the input of the first ADC 14, signals having significant levels (and corresponding to the input range of the first ADC 14).

The first ADC 14 thus digitises the voltage Vm1. The voltage measuring module 16 produces, from samples produced by the first ADC 14, (effective) voltage measurements making it possible to evaluate the neutral voltage VN.

The metrology part also comprises a current sensor arranged to produce current measurements representative of a phase current Iph circulating over the phase conductor 6.

The current sensor comprises a shunt 18 mounted on the phase conductor 6 and positioned between the input terminal UP and the switch 10 of the cutoff member 9.

The metrology part also comprises a current measuring chain 19 having a known gain. The current measuring chain 19 is connected to the terminal of the shunt 18 which is connected to the switch 10 of the cutoff member 9, the other terminal of the shunt 18 being connected to the ground 7 and to the input terminal UP.

The output of the current measuring chain 19 is connected to an input of the microcontroller 11 to which an input of the second ADC 15 is connected.

The voltage Vm2 at the output of the current measuring chain 19 is an image voltage of the phase current Iph.

The level of the voltage Vm2 is adapted (thanks to the gain of the current measuring chain 19) in order to avoid saturations at the second ADC 15, and so as to apply at the input of the second ADC 15, signals having significant levels (and corresponding to the input range of the second ADC 15).

The second ADC 15 digitises the voltage Vm2. The current measuring module 17 produces, from samples produced by the second ADC 15, current measurements making it possible to evaluate the phase current Iph.

The meter 1 in addition comprises a current limiter 20 arranged to selectively limit the current supplied to the installation 3 (phase current Iph).

The current limiter 20 comprises, in this case, a relay 21 for activating the current limitation (30A, typically), and a resistive component 22 connected in series with the relay 21. The relay 21 and the resistive component 22 are mounted in parallel of the switch 10 of the cutoff member 9.

More specifically, the relay 21 comprises a first terminal connected to the terminal of the switch 10 which is connected to the shunt 18, and a second terminal which is connected to a first terminal of the resistive component 22. The second terminal of the resistive component 22 is connected to the terminal of the switch 10 which is connected to the terminal of the output UP′ of the meter 1.

The resistive component is, in this case, a PTC thermistor (Positive Temperature Coefficient thermistor).

In this case, two component examples are provided which could be used:
Vishay 305C9 PTC: this component supports a peak current of 36 A and acts as a current limiter when the current reaches a few amps with a maximum consumed energy by the PTC of around 1 Watt;
TDK EPCOS PTC C840 PTC: this component corresponds to a peak current of 4.1 A and acts as a current limiter when the current reaches a few amps with a maximum consumed energy by the PTC of around 1 Watt.

The microcontroller 11 comprises an output 23 connected to the relay 21, by which the microcontroller 11 transmits to the relay 21, a command signal Cmde to operate it.

The activation of the current limiter 20 to limit the current supplied to the installation first consists of closing the relay 21, then of opening the switch 10 of the cutoff member 9.

Now, the monitoring method is described, which is, in this case, implemented by the microcontroller 11.

The monitoring method aims to limit or to cut off the electricity to avoid the consumption of the installation 3 being too high.

Each current day is divided into a predetermined set of at least one successive period Pk, k varying from 1 to N.

Each period Pk has, as a duration Hk and therefore has, for each current day:

$${\sum }_{k = 1}^{N} H k = 24 hours$$

The durations Hk and these periods Pk are not all necessarily identical.

The limitation and the control of the consumption are done period by period (and not daily, except if the current day comprises one single period).

These periods are preprogrammed in a predefined table which is stored in one of the memories 12 of the metrology part.

Each current day, for each current period, the microcontroller 11:
verifies a first predetermined condition associated with said current period;
if the first predetermined condition is verified, the microcontroller 11 activates the current limiter 20 to limit the current supplied to the installation 3 until the end of said current period.

In addition, for each current period, the microcontroller 11:
verifies a second predetermined condition associated with said current period;
if the second predetermined condition is verified, the microcontroller 11 operates the cutoff member 9 so as to cut off the current supplied to the installation 3 until the end of said current period.

In this case, the first predetermined condition is that a cumulated electricity consumption of the installation 3 over said current period is greater than a first predetermined threshold, and the second predetermined condition is that a cumulated electricity consumption of the installation 3 over said current period is greater than a second predetermined threshold, itself greater than the first predetermined threshold.

By “consumption”, in this case means any magnitude representative of the electrical energy distributed to the installation: current, energy, power, etc.

The first predetermined threshold and/or the second predetermined threshold can depend on said current period and/or on said current day and/or a period of the year to which said current day belongs.

It can indeed be relevant, for example, to authorise a greater consumption in the morning (before leaving for work or school) and in the evening (on return).

It can also be relevant, for example, to authorise a greater consumption at the weekend or during a public holiday.

It can further be relevant, for example, to authorise a greater consumption in the winter than in the summer.

The first predetermined thresholds and the second predetermined thresholds are therefore preprogrammed thresholds, which are associated in the predefined table of the memory 12 with the period of the predetermined set of successive periods.

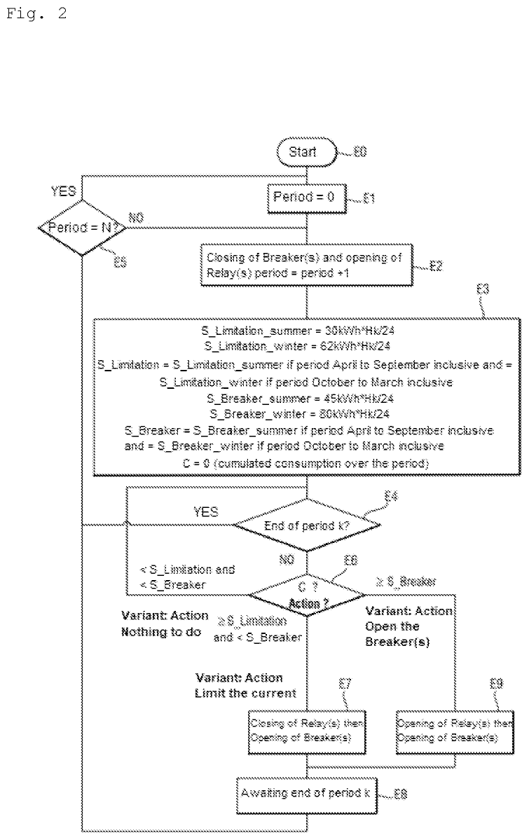

A particular embodiment of the monitoring method is described, in reference to FIG. 2.

The method starts at step E0.

The “Period” variable is initialised to 0 (step E1).

The microcontroller 11 closes the cutoff member 9 and opens the relay 21. The microcontroller 11 increments the Period variable:
Period=Period+1 (step E2).

The following variables are initialised by the microcontroller 11 (step E3):
S_Limitation_summer=30 kWh*Hk/24;
S_Limitation_winter=62 kWh*Hk/24;
S_Limitation=S_Limitation_summer if the current day belongs to a period going from April to September inclusive, and =S_Limitation_winter if the current day belongs to a period going from October to March inclusive;
S_Breaker_summer=45 kWh*Hk/24;
S_Breaker_winter=80 kWh*Hk/24;
S_Breaker=S_Breaker_summer if the current day belongs to a period going from April to September inclusive, and =S_Breaker_winter if the current day belongs to a period going from October to March inclusive.

S_Limitation is the first predetermined threshold and S_Breaker is the second predetermined threshold.

It is seen that, for each period, the predetermined thresholds are defined, in this case, pro rata of the duration of said period applied to the corresponding daily reference threshold (30 kWh, 62 kWh, 45 kWh, 80 kWh). Each current day, the thresholds therefore only depend on the duration of the period in question, and moreover, the thresholds depend on the period of the year to which the current day belongs (of the season: summer or winter).

The microcontroller 11 thus verifies if the present time corresponds to the end of the current period: step E4.

If this is the case, the microcontroller 11 verifies if the current period is the last of the current day, i.e. if:
Period=N (step E5).

If this is the case, the method goes back to step E1. Otherwise, the method goes to step E2.

In step E4, if the present time does not correspond to the end of the current period, the microcontroller 11 compares the cumulated consumption of the installation 3 over the current period with the first predetermined threshold (S_Limitation) and with the second predetermined threshold (S_Breaker): step E6.

If the cumulated consumption C is less (in this case, strictly) than the first predetermined threshold (and therefore than the second predetermined threshold),
i.e. if:
C<S_Limitation and C<S_Breaker,
the microcontroller 11 does not perform any particular action and the method goes back to step E4.

If the cumulated consumption is comprised between the first predetermined threshold (in this case, greater than or equal to this) and the second predetermined threshold (in this case, strictly less than this),
i.e. if:
S_Limitation≤C<S_Breaker,
the microcontroller 11 limits the current supplied to the installation 3. For this, the microcontroller 11 activates the current limiter 20 by closing the relay 21, then by opening the switch 10 of the cutoff member 9: step E7.

The microcontroller 11 thus awaits the end of the current period (step E8), then method goes to step E5.

In step E6, if the cumulated consumption is greater (in this case, greater than or equal to) that the second predetermined threshold,
i.e. if:
S_Breaker≤C,
the microcontroller 11 cuts off the current supplied to the installation 3 by opening the relay 21 and the switch 10 of the cutoff member 9: step E9.

The microcontroller 11 thus awaits the end of the current period (step E8), then method goes to step E5.

In the embodiment which has just been presented, the verification of the predetermined conditions, making it possible to decide to limit or to cut off the current during the current period, therefore comprises the step of comparing the cumulated consumption of the installation over the current period with predetermined thresholds.

In a second embodiment, the microcontroller 11 does not consider consumption thresholds. The microcontroller 11 simply verifies, for each current period of the current day, in a predefined table and preprogrammed in one of the memories 12, if, during said current period, it is provided: to limit the current supplied to the installation; to cut off the current; to not act at all on the current.

Thus, each current day, for each current period, the microcontroller 11 verifies a first predetermined condition associated with said current period. If the first predetermined condition is verified, the microcontroller 11 activates the current limiter to limit the current supplied to the installation 3 until the end of said current period.

The verification of the first predetermined condition consists of verifying, in the predefined table, that said current period is associated with a first piece of information, according to which the current supplied to the installation must be limited for the whole of said current period.

Likewise, the microcontroller 11 verifies a second predetermined condition associated with said current period. If the second predetermined condition is verified, the microcontroller 11 operates the cutoff member 9 so as to cut off the current supplied to the installation 3 until the end of said current period.

The verification of the second predetermined condition consists of verifying, in the predefined table, that said current period is associated with a second piece of information, according to which the current supplied to the installation 3 must be cut off during the whole of said current period.

Returning to FIG. 2, the implementation of this embodiment consists, in step E6, of verifying in the predefined table, if an action is associated with the current period. The actions, corresponding to this embodiment, are indicated in bold in FIG. 2.

If no action is provided, the method goes back to step E4.

If the action of limiting the current is provided, the method goes to step E7.

If the action of cutting off the current is provided, the method goes to step E9.

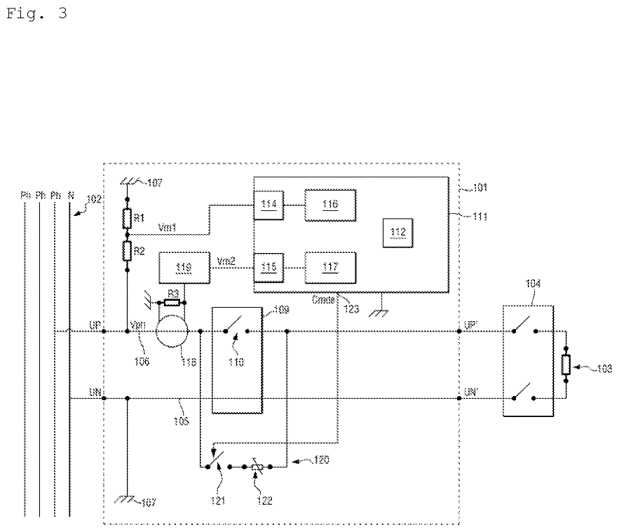

In reference to FIG. 3, the invention can naturally be implemented with an electricity meter 101 which is not a single-phase meter, but three-phase.

The distribution network 102 therefore comprises three phases Ph and one neutral N.

The circuit of the meter 101 is represented for only one phase in FIG. 3, but the pattern is the same for the 3 phases.

A circuit breaker 104 is positioned at the boundary between the distribution network 102 and the installation 103.

For each phase Ph of the network 102, the meter 101 comprises an input terminal UP connected to said phase Ph of the network 102. The meter 101 also comprises an input terminal UN connected to the neutral N. The meter 101 in addition comprises three output terminals UP′ and an output terminal UN′ connected to the circuit breaker 104, which is itself connected to the installation 103.

The meter 101 comprises a neutral conductor 105 connected to the input terminal UN. The neutral conductor 105 is connected to an electrical ground 107 of the meter 101.

The meter 101 comprises three phase conductors 106, each phase conductor 106 being connected to a distinct input terminal UP.

The meter 101 in addition comprises a cutoff member 109 which comprises three switches 110, i.e. a switch 110 mounted on each phase conductor 106.

The metrology part comprises a metrological measurement microcontroller 111 which integrates one or more memories 112, a first ADC 114, a second ADC 115, a voltage measuring module 116 and a current measuring module 117.

For each phase, the metrology part also comprises a voltage sensor arranged to produce voltage measurements to evaluate a phase voltage Vph present on said phase Ph. In this case, the voltage sensor comprises a voltage divider bridge comprising a first measurement resistor R1 and a second measurement resistor R2. The first ADC 114 digitises the voltage Vm1.

The first ADC 114 therefore comprises three inputs each connected to the voltage divider bridge associated with one of the phases Ph.

The voltage measuring module 116 produces, from samples produced by the first ADC 114, (effective) voltage measurements making it possible to evaluate the phase voltages Vph.

For each phase Ph, the metrology part also comprises a current sensor arranged to produce current measurements representative of a phase current Iph circulating over the phase conductor 106. The current sensor comprises a core 118 mounted on the phase conductor 106 upstream of the switch 110 of the cutoff member 109. A third measurement resistor R3 is mounted between the output terminals of the core 118.

The metrology part also comprises a current measuring chain 119 having a known gain. The current measuring chain 119 is connected to a terminal of the third measurement resistor R3, the other terminal of the measurement resistor R3 being connected to the ground 107.

The second ADC 115 digitises the voltage Vm2.

The second ADC 115 therefore comprises three inputs, each connected to the current measuring chain 117 associated with one of the phases Ph.

The current measuring module 117 produces, from samples produced by the second ADC 115, current measurements making it possible to evaluate the phase currents Iph.

The meter 101 in addition comprises a current limiter 120 arranged to selectively limit the current supplied to the installation 3 (comprising the phase currents).

For each phase Ph, the current limiter 120 is similar to that described in FIG. 1, and comprises a relay 121 for activating the current limitation, and a resistive component 122 connected in series with the relay 121. The relay 121 and the resistive component 122 are mounted in parallel of the switch 110 of the cutoff member 109 which is mounted on said phase Ph.

The components of the limiter 120 (relay, PTC-type resistive component), presented for the single-phase meter, can be used for the three-phase meter.

The microcontroller 111 comprises one single output 123 connected to the three relays, by which the microcontroller 111 transmits to the relays, one same command signal Cmde to operate them.

The command Cmde is therefore unique for the three phases Ph such that it is simultaneous (the three activation relays 121 are either all open, or all closed).

The monitoring method (and, in particular, the embodiment presented in FIG. 2) is implemented in the same way as in the case of the single-phase meter 1.

To limit the current, the microcontroller 111 first closes the three relays 121 simultaneously, then opens the three switches 110 of the cutoff member 109 simultaneously.

To cut off the current, the microcontroller 111 opens the three relays 121 simultaneously, and opens the three switches 110 of the cutoff member 109 simultaneously.

It is noted that the service, i.e. the monitoring and the limitation of the consumption, must in practice be “authorised” by the operator (i.e. by the energy distributor or by the network manager), in particular when equipment which is sensitive for the health of the user is present at their place.

It is also noted that the values of the durations Hk of the periods Pk are typically deduced from the typical consumption profile corresponding to the charge curves which give consumption values every 10 minutes or every half hour, typically.

Naturally, the invention is not limited to the embodiments described, but includes any variant entering into the field of the invention such as defined by the claims.

The invention naturally applies to any multiphase meter (not only three-phase).

The current limiter can be different from that described in this case. It could be, for example, for each phase conductor, one single component integrating a switch (or relay) and a resistive component, and mounted directly on the phase conductor.

It has been indicated that the monitoring method is implemented in the microcontroller of the metrology part.

The monitoring method could also be implemented in the microcontroller of the application part.

More generally, the monitoring method can be implemented in any processing unit which comprises at least one processing component and at least one memory connected or integrated in one of the processing components. The processing component is, for example, a “general” processor, a processor specialising in processing the signal (or DSP, for Digital Signal Processor), a microcontroller (as in this case), or a programmable logic circuit, such as an FPGA (for Field Programmable Gate Array) or an ASIC (for Application-Specific Integrated Circuit).

The monitoring method, i.e. the monitoring of the consumption and the operating of the current limiter and of the cutoff member, is not necessarily fully implemented in the meter. The monitoring method could be implemented at least partially outside of the meter.

For example, the operator (i.e. the energy distributor or the network manager) can remotely manage the command Cmde of the relay(s) of the limiter and that of the switch(es) of the cutoff member according to daily time periods pre-adjusted for each end user. Thus, in certain time ranges of the day, the operator can enable at the user's place, the current limiter or a current cutoff for a predefined duration. The operator thus transmits the commands to the meter via any communication means (for example, cellular, by power line carriers, etc.), and remotely operates the limiter and the cutoff member (via the microcontroller 11, optionally).

The operator could also acquire the consumption measurements produced by the meter (which transmits them via the communication means which have just been mentioned), then check, period by period, the predetermined conditions. The operator thus transmits the commands to the meter.

1. A monitoring method, using an electricity meter arranged to measure an electricity consumption of an installation and comprising a current limiter arranged to selectively limit a current supplied to the installation, the monitoring method comprising the steps, repeated each current day, for each current period of a predetermined set of at least one successive period defined in the current day, of:
verifying a first predetermined condition associated with said current period;
if the first predetermined condition is verified, activating the current limiter to limit the current supplied to the installation until the end of said current period, the electricity meter in addition comprising a cutoff member arranged to selectively cut off the current supplied to the installation, the monitoring method further comprising the steps, for each current period, of:
verifying a second predetermined condition associated with said current period;
if the second predetermined condition is verified, operating the cutoff member so as to cut off the current supplied to the installation until the end of said current period.

2. The monitoring method according to claim 1, wherein the first predetermined condition is that a cumulated electricity consumption of the installation over said current period is greater than a first predetermined threshold.

3. The monitoring method according to claim 2, wherein the second predetermined condition is that a cumulated electricity consumption of the installation over said current period is greater than a second predetermined threshold, itself greater than the first predetermined threshold.

4. The monitoring method according to claim 2, wherein the first predetermined threshold and/or the second predetermined threshold depend on said current period and/or on said current day and/or on a period of the year to which said current day belongs.

5. The monitoring method according to claim 1, wherein the verification of the first predetermined condition consists of verifying, in a predefined table, that said current period is associated with a first piece of information, according to which the current supplied to the installation must be limited for the whole of said current period.

6. The monitoring method according to claim 5, wherein the verification of the second predetermined condition consists of verifying, in the predefined table, that said current period is associated with a second piece of information, according to which the current supplied to the installation must be cut off for the whole of said current period.

7. The monitoring method according to claim 1, the meter in addition comprising a cutoff member arranged to selectively cut off the current supplied to the installation, the cutoff member comprising a switch for each phase of a distribution network to which the installation is connected, the current limiter comprising, for each switch of the cutoff member, a relay and a resistive component mounted in parallel of the switch, the activation of the current limiter to limit the current supplied to the installation comprising the steps of closing the relay(s) simultaneously then of opening the switch(es) simultaneously.

8. An electricity meter arranged to measure an electricity consumption of an installation, the electricity meter comprising a current limiter arranged to selectively limit a current supplied to the installation, the electricity meter further comprising a processing unit arranged to implement the monitoring method according to claim 1.

9. The electricity meter according to claim 8, the electricity meter in addition comprising a cutoff member arranged to selectively cut off the current supplied to the installation, the cutoff member comprising a switch for each phase of a distribution network to which the installation is connected, the current limiter comprising, for each switch of the cutoff member, a relay and a resistive component mounted in parallel of the switch, the processing unit being arranged, to activate the current limiter, to close the relay(s) simultaneously, then to open the switch(es) simultaneously.

10. (canceled)

11. A non-transitory recording medium which can be read by a computer, on which a computer program is recorded, wherein the computer program comprises instructions which lead a processing unit of an electricity meter arranged to measure an electricity consumption of an installation, the electricity meter comprising a current limiter arranged to selectively limit a current supplied to the installation, the electricity meter further comprising a processing unit arranged to implement the monitoring method according to claim 1.
